(19) United States
(12) Patent Application Publication
(10) Pub. No.: US 2003/0151132 A1
(43) Pub. Date: Aug. 14, 2003

(54) Microelectronic die providing improved heat dissipation, and method of packaging same

(76) Inventor: Warren Stuart Crippen, Mesa, AZ (US)

Correspondence Address: KENYON & KENYON, 1500 K STREET, N.W., SUITE 700, WASHINGTON, DC, 20005, US

(21) Appl. No.: 10/073,859

(22) Filed: Feb. 14, 2002

(51) Int. Cl. H01L 23/34

(52) U.S. Cl. 257/713; 257/712; 438/584; 438/687

(57) ABSTRACT

A microelectronic die and a method of packaging the die. A thermally conductive material, such as copper, is placed in an inner region located between a die substrate, such as a silicon wafer, and a dielectric, such as a subsequent silicon layer. A microelectronic circuit is provided on at least one of the die substrate and the dielectric. Thermal contact is established between an outer region located outside of the inner region and the thermally conductive material placed in the inner region to effect a dissipation of heat away from the microelectronic circuit.

### BACKGROUND OF THE INVENTION

This invention generally relates to microelectronic dies, and more particularly to heat dissipating structures for such dies.

The computer industry has as one of its goals the continued and increased miniaturization of integrated circuit components. Increased miniaturization among other things means increased density of the integrated circuits, which underscores the importance of providing effective heat dissipation for the circuits.

Heat dissipation from integrated circuits is typically achieved using thermal epoxy as a method of attaching a heat spreader to bare silicon on the back side of the die, as shown in FIG. 1A. In the alternative, solder may be used to attach the heat spreader to a thin layer of metal sputtered on the bare silicon on the back side of the die, as shown in FIG. 1B. In both FIGS. 1A and 1B, a microelectronic die package 100 is provided including a heat spreader 110 thermally coupled with a thermal coupling layer 120 to a processor 130 that is electrically coupled to a printed circuit board 140. In FIG. 1A, layer 120 is a layer of thermal epoxy, while in FIG. 1B, layer 120 is a layer of solder.

Thermal epoxy has heat transfer limitations that impede efficient heat transfer from the die. Although solder has better heat transfer properties than thermal epoxy, it requires metallization, such the deposition of metal as a thin layer of gold, on the back side of the die, as indicated by layers 150 in FIG. 1B. In addition, in both the thermal epoxy alternative and the solder alternative, heat is transferred from the package essentially through a layer of dielectric as the processor substrate, such as silicon. However, silicon is a poor thermal conductor, typically having a thermal conductivity of 148 W/m/K. Disadvantageously, the heat spreader in both of the attachment schemes described above requires a heat spreader to be attached to the die with a relatively large amount of silicon, for example, a silicon layer having a thickness between about 5 to about 200 microns, disposed between the heat spreader and the circuit generating the heat.

The prior art fails to offer a microelectronic die that allows an effective dissipation of heat from the die while at the same time allowing higher microprocessor speeds and/or further miniaturization of integrated circuits incorporating the die.

### BRIEF DESCRIPTION OF DRAWINGS

The present invention is illustrated by way of example and not limitation in the figures in the accompanying drawings in which like references indicate similar elements, and in which:

FIG. 1A is a schematic, cross-sectional view of part of a microelectronic package according to the prior art using thermal epoxy as the thermal coupling material;

FIG. 1B is a schematic, cross-sectional view similar to FIG. 1A showing a microelectronic package according to the prior art using solder as the thermal coupling material;

FIG. 2 is a schematic, perspective view of a bare silicon wafer into which a plurality of vias are being laser etched according to one embodiment of the present invention;

FIG. 3 is a schematic view similar to FIG. 2, showing a layer of adhesion promoter as having been deposited on a silicon wafer etched as shown in FIG. 2 according to an embodiment of the present invention;

FIG. 4 is a schematic view similar to FIG. 2, showing a layer of copper as having been deposited on the layer of adhesion promoter of FIG. 3, according to an embodiment of the present invention;

FIG. 5 is a schematic view similar to FIG. 2 showing a silicon layer as having been disposed on the layer of copper of FIG. 4 to provide a dielectric-thermal conductor sandwich, according to an embodiment of the present invention;

FIG. 6 is a schematic view similar to FIG. 2 showing an intermediate die built up according to any one of standard manufacturing processes and incorporating the dielectric-thermal conductor sandwich shown in FIG. 5 according to an embodiment of the present invention;

FIG. 7 is a schematic view similar to FIG. 2 showing a die made by etching the intermediate die of FIG. 6 to expose thermal contact zones at the bottom of vias provided therein, according to an embodiment of the present invention;

FIG. 8 is a schematic, perspective view of a die made according to an embodiment of a method of the present invention, the die having been coupled to a printed circuit board to provide an intermediate die package; and

FIG. 9 is a schematic view similar to FIG. 8 depicting the intermediate die package of FIG. 8 as having been attached to a heat spreader through a thermal interface material to provide a die package, according to an embodiment of the present invention.

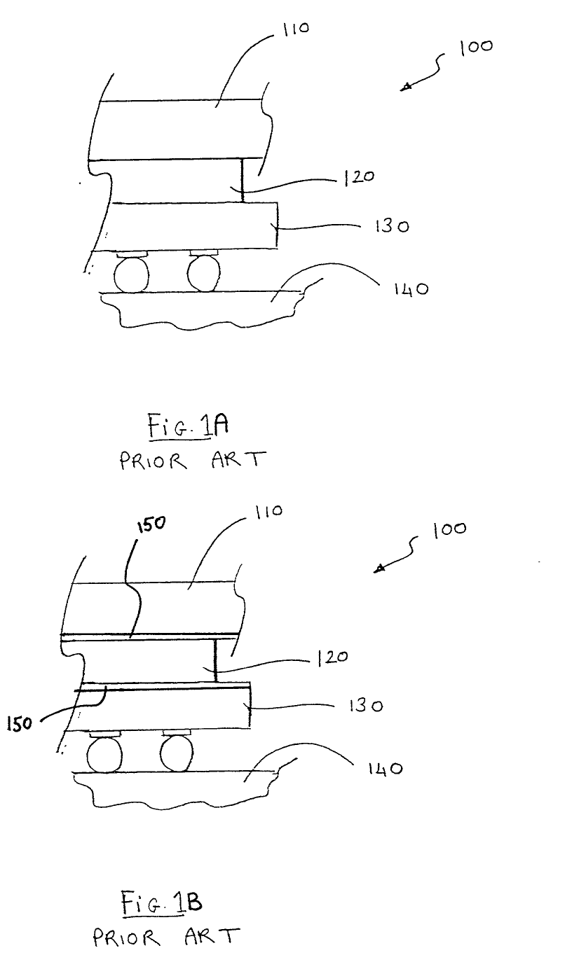

### DETAILED DESCRIPTION OF THE INVENTION

Embodiments of the present invention contemplate the inclusion of a thermally conductive material, such as copper, in an inner region of a microelectronic die for effecting heat dissipation from the inner region of the die through the thermally conductive material and away from the die. By “microelectronic die,” what is meant is a microelectronic package including a microelectronic circuit, such as a microprocessor. As is well known, microelectronic dies generate heat when being operated. The thermally conductive material in the inner region of the die draws the heat away from the microelectronic circuit, according to embodiments of the present invention. The thermally conductive material may comprise a copper layer, but any other suitable thermal conductor can be used, as recognized by one skilled in the art. The heat dissipation would take place through the copper layer and through thermal contact zones comprising copper connections to a heat spreader attachment mechanism, The efficiency of the heat transfer process from a die packaged according to embodiments of the present invention is increased relative to dies packaged according to the prior art. Embodiments of the present invention use a thermally conductive material, such as copper, to draw heat from the inner region of the die and to transfer it away from the die, such as to a heat spreader, thus improving the overall heat transfer characteristics of the package. The heat transfer from the inner region of the die to the heat spreader may be effected through thermal contact zones that include copper filled thermal vias, and thereafter may be effected through solder, to a heat spreader. Embodiments of the present invention advantageously allow higher processor speeds by improving heat dissipation from microelectronic dies. By way of example, where copper is used as the thermally conductive material in the inner region of the die, there would be approximately a threefold increase in the heat dissipation from the die with respect to dies relying solely on a dielectric material, such as silicon, for the dissipation of heat.

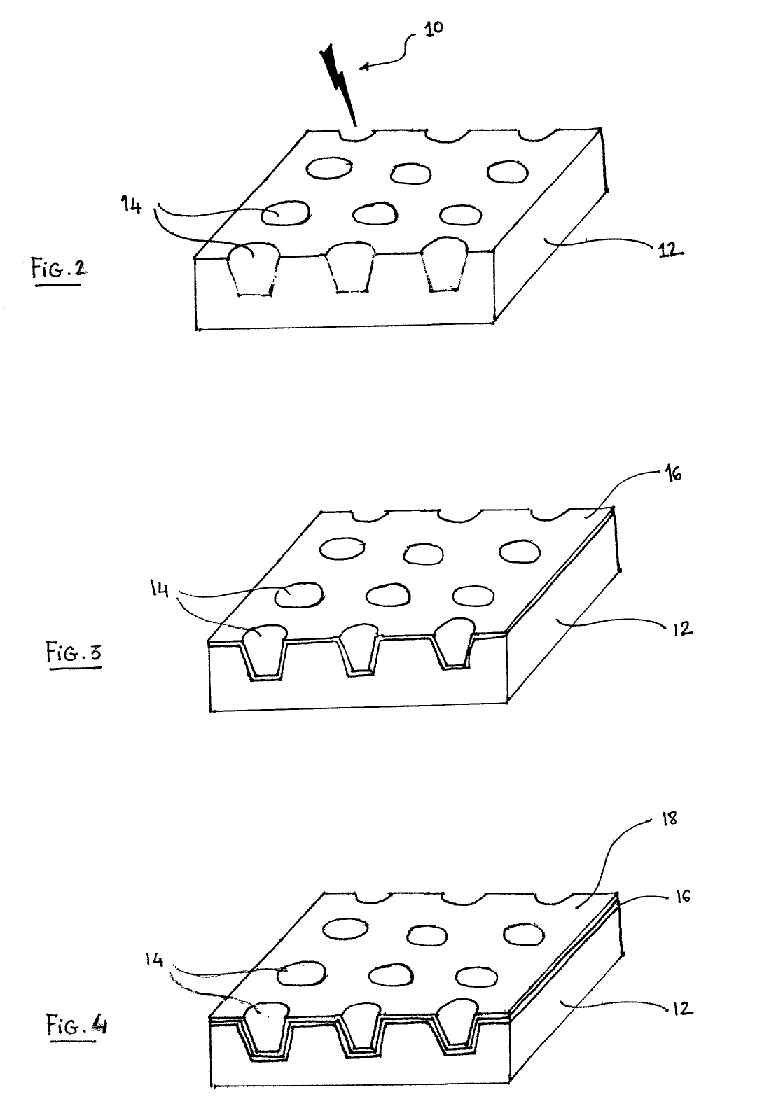

Turning now to the drawings, FIGS. 2-7 depict various stages of the packaging of a microelectronic die according to one embodiment of the present invention. Referring more particularly to FIG. 2, a method according to one embodiment of the present invention involves starting from a bare dielectric wafer or substrate, such as a bare silicon wafer, and etching vias into the wafer, for example using laser beams, as depicted schematically by beams 10. The laser beams 10 create vias 14 in the wafer, resulting in the initial die substrate shown in FIG. 2. It is to be noted that embodiments of the present invention include within their scope use of any other suitable dielectric material besides silicon, and of any other suitable methods of providing vias in silicon, as readily recognizable by one skilled in the art.

A high density of relatively large vias may be provided onto the substrate. The range of vias per surface area that would qualify as high density in the context of embodiments of the present invention is dependent on the size of the vias. Large vias may be used that will have a pitch that is relatively large but that will allow a large area to be covered by the thermal contact zones formed in these vias. See thermal contact zones 28 in FIG. 7. The pitch of the vias is defined as the distance between the respective centerlines of adjacent vias. Thus, “high density” in the context of embodiments of the present invention is a function of the size of the thermal contact zones formed in the vias and of the pitch of the vias for a given area. By way of example, for a thermal contact zone diameter of about 100 microns and a via pitch of about 150 microns, a density of about 49 thermal contact zones per millimeters squared would qualify as high density according to embodiments of the present invention. Another example would be a density of about 16 thermal contact zones per millimeters squared for a thermal contact zone diameter of about 200 microns and a via pitch of about 250 microns. The thermal contact zone diameters noted above are large compared to standard signal pad sizes that are typically in the order of about 25 microns or less. The above two densities are merely examples of likely configurations according to embodiments of the present invention, and are not meant to be exhaustive of the possibilities thereof. A given density will be chosen according to embodiments the present invention as a function of die size and optimized to provide the most stable wafer condition that will maximize the surface area of the thermal contact zones on the backside of the die, as shown for example in FIG. 9.

After creating the vias in the substrate, according to an embodiment of the present invention as depicted in FIG. 3, a layer of an adhesion promoter 16, such as, for example, silicon oxide is deposited on the initial die substrate. The layer of adhesion promoter is of a thickness typically measured in Angstroms. Tantalum could in turn be deposited onto the silicon oxide to enhance its adhesion promotion properties. The purpose of the adhesion promoter is to enhance an adhesion of a thermal conductor layer thereon, as described in further detail with respect to FIG. 4. Another alternative for an adhesion promoter includes trichlorosilane. As seen in FIG. 3, the adhesion promoter 16 is deposited on the top flat surface of the die substrate 12, and in the vias of the substrate.

Referring now to FIG. 4, a layer of copper 18 is deposited on top of the layer of adhesion promoter 16 so as to at least partially fill vias 14 as shown. The deposition of the adhesion promoter and of the layer of thermally conductive material as depicted in FIGS. 3 and 4 may be achieved according to know methods as readily recognizable by one skilled in the art. The layer of adhesion promoter may be deposited using vapor deposition. Many other alternatives are also possible according to embodiments of the present invention, such as, for example, chemical deposition. For example, the layer of thermally conductive material, such as copper, may be deposited onto the die substrate by using conventional plating methods. The thickness of the layer of thermally conductive material is predetermined as a function of the deposition technology, and is optimized for thermal transfer. According to an embodiment of the present invention, where copper is used as the layer of thermally conductive material, the copper layer may have a thickness of between about 25 Angstroms to about 1 micron.

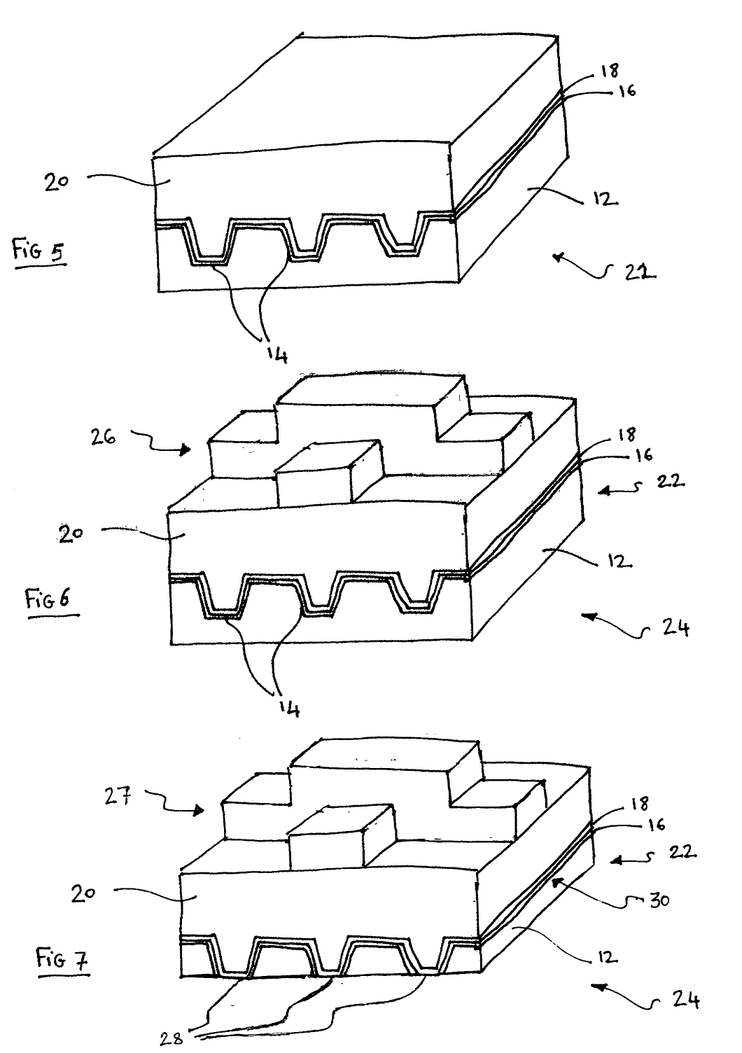

Referring now to FIG. 5, a schematic view is provided showing a silicon layer 20 as having been disposed on the layer of copper 18 of FIG. 4 to provide a dielectric-thermal conductor “sandwich” 22 according to one embodiment of the present invention. By “dielectric-thermal conductor sandwich,” what is meant in the context of embodiments of the present invention is that a thermal conductor, such as copper, is disposed between two dielectric layers, such as, as in the case of the embodiment shown in FIGS. 4 and 5, the layer of copper 18 sandwiched between the silicon layer 12 and the silicon layer 20. The silicon layer 20 may comprise poly-silicon, having a sufficient thickness to allow conventional semi-conductor device pattern base layer and build up based on application needs. The silicon layer 20 may, for example, measure between about 50 Angstroms to about 1 micron in thickness.

Referring next to FIG. 6, a schematic view is provided of an intermediate die 24 built up according to any one of standard manufacturing processes and incorporating the dielectric-thermal conductor sandwich 22 shown in FIG. 5. The intermediate die 24 incorporates standard build up layers 26. The build up layers 26 may comprise any number of layers including signal and dielectric layers for providing a microelectronic circuit such as a microprocessor, as readily recognized by one skilled in the art. The building up of layers 26 takes place, according to embodiments of the present invention, upon a thermally conductive microelectronic die substrate, such as the dielectric-thermal conductor sandwich shown in FIG. 5. By “thermally conductive microelectronic die substrate,” what is meant in the context of embodiments of the present invention is a die substrate, such as a silicon wafer, on which a thermally conductive material is provided that allows the formation of thermal contact zones as shown by zones 28 in FIG. 7. According to the above definition, the substrate and layer of copper combination shown in FIG. 4 is also a thermally conductive microelectronic die substrate.

As seen in FIG. 7, according to one embodiment of the present invention, the intermediate die 24 of FIG. 6 is etched, prior to dicing for standard packaging, for exposing thermal contact zones 28 at the etched face of the die for providing a die 27. In the embodiment shown in FIG. 7, the thermal contact zones 28 comprise exposed parts of the copper layer 12 disposed in vias 14. The thermal contact zones allow a dissipation of heat from an inner region 30 of the die 27 away from the die. The etching may be effected using conventional atmospheric downstream plasma etching technology, although it is to be understood that other conventional methods may be used, as readily recognizable by one skilled in the art. As is well known, plasma etching is a process that utilizes an electrically excited gas to remove material from a device or unit. Selective plasma etching refers to a process that removes only specific materials, such as, in the case of the present invention as depicted in FIGS. 2-9, removing only the dielectric layer and not the layer of thermally conductive material.

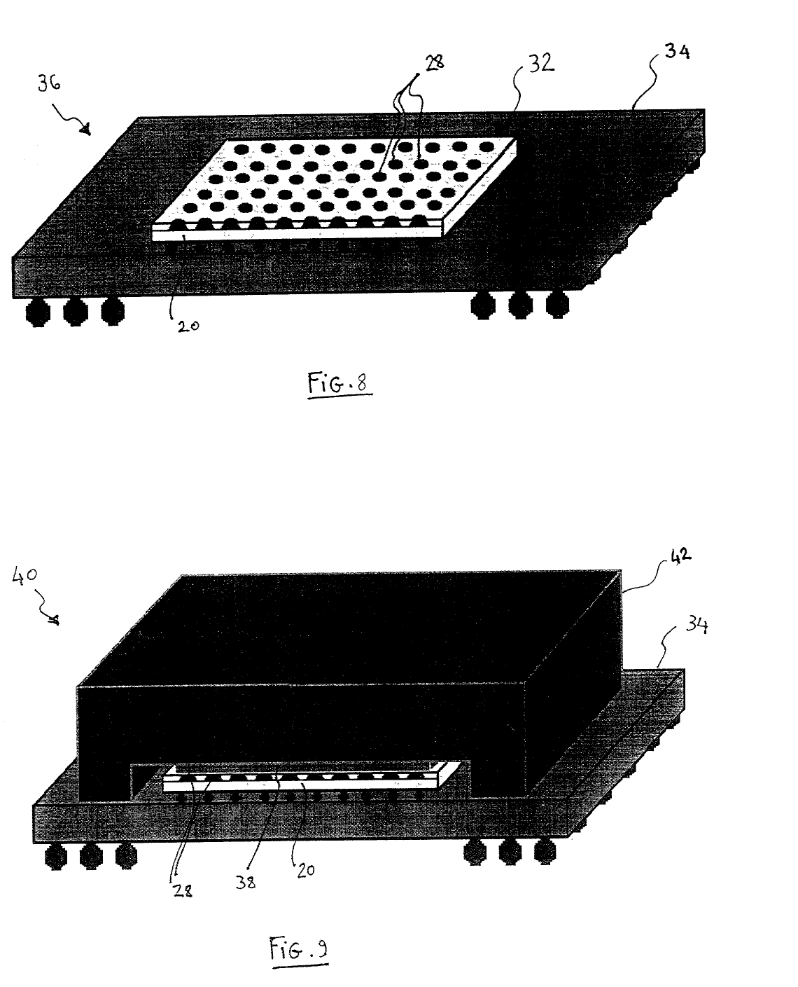

Referring now to FIGS. 8 and 9, stages of packaging of die 27 are shown up to the attachment of a heat spreader. In particular, referring to FIG. 8, a die 32 made according to the process of the present invention, such as the process described with respect to the embodiment of FIGS. 2-7 to make die 27, is coupled to a conventional printed circuit board 34 to provide an intermediate die package 36. As seen in FIG. 8, the thermal contact zones 28 on the top face of die 32 are shown as having been exposed. Referring thereafter to FIG. 9, a layer of thermal interface material 38, such as solder, is disposed using conventional methods, onto the exposed face of die 32 to be in thermal contact with thermal contact zones 28 as shown. By way of example, the solder may be placed over the copper thermal contact zones 28 as a paste, ribbon or plug, as readily recognizable by one skilled in the art. A heat dissipation device, such as a heat spreader 42, is thereafter attached to the layer 38 of interface material to provide a final microelectronic die package 40 as shown.

The attachment of the heat dissipation device may be effected through a conventional reflowing process where the thermal interface material provides a metal-to-metal connection between the thermal connection zones and the heat dissipation device. In the shown embodiment, the heat spreader 42 may thus be attached by reflowing the shown package to effect a metal-to-metal connection between the copper at thermal contact zones 28 and the heat spreader 42. As is well known, reflowing is a process of heating a material past its melting point and allowing it to cool and solidify thereafter. In the case of the embodiment of the present invention as depicted in the figures, and, in particular, in FIG. 9, solder 38, an alloy of tin and lead, or other material and/or alloy such as indium and indium-lead, is placed on the die 32, the heat spreader 42 is placed on top of the solder 38, and the entire package is subjected to heat above the solder's melting point, causing the solder to flow and attach to the heat spreader and to the die. The solder is then cooled to allow it to solidify.

As best seen in FIG. 9, the die package according to embodiments of the present invention allows for the placement of a plane of thermally conductive material, such as copper, very close, such as within a distance from about 1 micron to 2 microns, to the circuitry generating heat, such as circuit board 34. There is thus only a very thin silicon interface 20 through which heat must be conducted before it reaches the copper plane and is dissipated through the vias. The reduction of thermally isolating dielectric material between the circuitry and the heat spreader, and, in addition, the use of a direct thermal connection to the inner region of the die both work to improve heat dissipation away from the die.

Embodiments of the present invention are not limited to the use of solder as a thermal interface material 38. Embodiments of the present invention further include within their scope the use of other thermal interface materials, such as, for example, organic thermal epoxy. While heat dissipation for a die package using organic thermal epoxy as the thermal interface material will be less than that for solder, the die package as a whole will exhibit a significant improvement in heat dissipation as compared with the use of thermal epoxy in die packages made according to prior art methods, where thermal epoxy is placed on a layer of silicon.

Thus, according to an embodiment of the present invention, thermal contact is established between the inner region of a die and an outer region located outside of the inner region by exposing the thermal contact zones, applying a thermal interface material such as solder to the thermal contact zones, and thereafter placing a heat dissipation device such as a heat spreader over the thermal interface material. Thermal contact elements that allow heat to be drawn from the inner region of the die, according to the described embodiment, include the thermal interface material and the heat dissipation device.

Embodiments of the present invention further encompass a microelectronic die package that comprises a die substrate, a layer of dielectric mounted to the die substrate, means disposed in an inner region located between the die substrate and the layer of dielectric for effecting a dissipation of heat away from the microelectronic circuit, and means in thermal contact with the means for effecting for directing heat away from the microelectronic circuit through the means for effecting. An example of the means for effecting comprises the layer of copper 8 shown in FIG. 4, while an example of the means for directing comprises the solder layer 38 and heat spreader 42 shown in FIG. 9. Other such means would be well known by persons skilled in the art.

Advantageously, the method of packaging and microelectronic package according to embodiments of the present invention allow for improved thermal conduction from an inner region of the die away from the die, such as to a heat dissipation device, increasing the ability of the heat dissipation device to remove and dissipate heat from the die. Embodiments of the present invention are applicable to all semiconductor devices requiring heat dissipation.

The invention has been described with reference to specific exemplary embodiments thereof. It will, however, be evident to persons having the benefit of this disclosure, that various modifications and changes may be made to these embodiments without departing from the broader spirit and scope of the invention. The specification and drawings are, accordingly, to be regarded in an illustrative rather than in a restrictive sense.

What is claimed is:

1. A method of packaging a microelectronic die, comprising:
placing a thermally conductive material on a die substrate; and
establishing thermal contact between an outer region located outside of the inner region and the thermally conductive material placed in the inner region to effect a dissipation of heat away from the die.

2. The method according to claim 1, wherein establishing thermal contact includes:
etching the die substrate to expose thermal contact zones of the thermally conductive material; and
placing a heat dissipation device in thermal contact with the thermal contact zones.

3. A method of packaging a microelectronic die, comprising:
depositing a layer of thermally conductive material on a die substrate;
depositing a layer of dielectric on the layer of thermally conductive material such that the layer of thermally conductive material is placed in an inner region located between the die substrate and the layer of dielectric;
providing a microelectronic circuit the layer of dielectric; and
establishing thermal contact between an outer region located outside of the inner region and the layer of thermally conductive material placed in the inner region to effect a dissipation of heat away from the microelectronic circuit.

10. The method according to claim 3, further comprising depositing an adhesion promoter on the die substrate before depositing the layer of thermally conductive material to enhance an adhesion of the layer of thermally conductive material to the die substrate.

11. A method of packaging a microelectronic die, comprising:
creating a plurality of vias in a silicon wafer;
depositing a layer of copper on the silicon wafer such that at least some of the copper is deposited in the plurality of vias;
depositing a layer of silicon on the layer of copper such that the layer of copper is placed in an inner region located between the silicon wafer and the layer of silicon;
providing a microelectronic circuit on the layer of silicon; and
establishing thermal contact between an outer region located outside of the inner region and the layer of copper placed in the inner region to effect a dissipation of heat away from the microelectronic circuit, establishing thermal contact including:
etching the silicon wafer to expose a plurality of thermal contact zones of the layer of copper, each of the thermal contact zones corresponding to a location of a respective one of the plurality of vias;
applying solder to each of the thermal contact zones; and
placing a heat dissipation device over the solder to create a first package to effect a dissipation of heat away from the microelectronic circuit through the solder and the heat dissipation device.

12. The method according to claim 11, wherein placing includes attaching the heat dissipation device to the solder by reflowing the first package.

13. A microelectronic die package comprising:
a die substrate;
a layer of dielectric mounted to the die substrate;
a thermally conductive material disposed in an inner region located between the die substrate and the layer of dielectric; and
thermal contact elements disposed between an outer region located outside of the inner region and the thermally conductive material disposed in the inner region to effect a dissipation of heat away from the die.

14. The microelectronic die package according to claim 13, wherein:
the thermally conductive material defines thermal contact zones; and
the thermal contact elements comprise a heat dissipation device in thermal contact with the thermal contact zones.

15. The microelectronic die package according to claim 13, wherein:
the thermally conductive material comprises a layer of thermally conductive material;
the die substrate defines at least one via therein, at least some of the layer of thermally conductive material being located in the at least one via, the at least some of the layer of thermally conductive material further defining the thermal contact zones and being in thermal contact with the thermal contact elements.

16. The microelectronic die package according to claim 15, wherein the thermal contact elements comprise:
solder in thermal contact with the thermal contact zones; and
a heat dissipation device in thermal contact with the solder.

17. The microelectronic die package according to claim 16, wherein the heat dissipation device is attached to the solder.

18. The microelectronic die package according to claim 13, further comprising an adhesion promoter disposed between the thermally conductive material and the die substrate to enhance an adhesion of the layer of thermally conductive material to the die substrate.

19. A microelectronic die package comprising:
a silicon wafer defining a plurality of vias therein;
a layer of copper on the silicon wafer, at least some of the copper being disposed in the plurality of vias to define thermal contact zones in the plurality of vias;
a layer of silicon disposed on the layer of copper, the layer of copper being disposed in an inner region located between the silicon wafer and the layer of silicon;
a microelectronic circuit provided on the layer of silicon; and
thermal contact elements disposed between an outer region located outside of the inner region and the layer of copper in the inner region to effect a dissipation of heat away from the microelectronic circuit, the thermal contact zones in the plurality of vias being in thermal contact with the thermal contact elements, the thermal contact elements comprising:
solder in thermal contact with the thermal contact zones in the plurality of vias; and
a heat dissipation device in thermal contact with the solder.

20. The microelectronic die package according to claim 19, wherein the heat dissipation device is attached to the solder.

21. The microelectronic die package according to claim 19, further comprising an adhesion promoter disposed between the layer of copper and the silicon wafer to enhance an adhesion of the copper to the silicon wafer.

22. A thermally conductive microelectronic die substrate for a microelectronic die comprising:
a die substrate; and
a thermally conductive material provided on the die substrate and defining thermal contact zones configured to effect a dissipation of heat away from the die.

23. The thermally conductive microelectronic die substrate according to claim 22, further comprising a layer of dielectric mounted to the die substrate, the thermally conductive material being disposed in an inner region between the die substrate and the layer of dielectric.

24. The thermally conductive microelectronic die substrate according to claim 23, wherein:
the die substrate comprises a silicon wafer;
the layer of dielectric comprises a layer of silicon mounted to the silicon wafer; and
the thermally conductive material comprises a layer of copper in the inner region, the silicon wafer further defining at least one via therein, and some of the layer of copper being disposed in the at least one via to define the thermal contact zones.

25. A microelectronic die package comprising:
a die substrate;
a layer of dielectric mounted to the die substrate;
means disposed in an inner region located between the die substrate and the layer of dielectric for effecting a dissipation of heat away from the microelectronic circuit; and
means in thermal contact with the means for effecting for directing heat away from the die through the means for effecting.

26. The die according to claim 25, wherein the means for effecting comprises a layer of copper.

27. The die according to claim 25, wherein the means for directing comprises a heat dissipation device.
